(19) United States
(12) Patent Application Publication
(10) Pub. No.: US 2015/0084075 A1
(43) Pub. Date: Mar. 26, 2015

(54) Light-Emitting Module and Luminaire

(71) Applicant: TOSHIBA LIGHTING & TECHNOLOGY CORPORATION, Yokosuka-shi (JP)

(72) Inventor: Miho Watanabe, Yokosuka-shi (JP)

(73) Assignee: TOSHIBA LIGHTING & TECHNOLOGY CORPORATION, Yokosuka-shi (JP)

(21) Appl. No.: 14/200,047

(22) Filed: Mar. 7, 2014

(30) Foreign Application Priority Data
Sep. 24, 2013 (JP) 2013-197362

(51) Int. Cl. H01L 33/50

(52) U.S. Cl. CPC H01L 33/504
USPC 257/98

(57) ABSTRACT

According to one embodiment, there is provided a light-emitting module including a substrate, a light-emitting body provided on the substrate, and a phosphor containing layer provided on the substrate and the light-emitting body, the phosphor containing layer including a first phosphor excited by emitted light of the light-emitting body, having a light emission peak in a wavelength range equal to or greater than 610 nm and less than 655 nm, and having a surface covered with a protection film.

### CROSS-REFERENCE TO RELATED APPLICATIONS

This application is based upon and claims the benefit of priority from Japanese Patent Application No. 2013-197362, filed on Sep. 24, 2013; the entire contents of which are incorporated herein by reference.

### FIELD

Embodiments described herein relate generally to a light-emitting module and a luminaire.

### BACKGROUND

As a light source of a luminaire, a light-emitting module mounted with a semiconductor chip is being used. For example, there is a light-emitting module in which a semiconductor chip configured to emit blue light and a phosphor configured to emit yellow light are combined to obtain white light. In order to improve an average color rendering index Ra, it is conceivable to combine red and green phosphors. However, the red phosphor and the green phosphor have external quantum efficiency lower than external quantum efficiency of a yellow phosphor. Therefore, if the red phosphor and the green phosphor are used, light-emitting efficiency is deteriorated.

In order to improve the light-emitting efficiency, it is conceivable to incorporate, in a light-emitting module, instead of the red phosphor, a semiconductor chip configured to emit red color. The average color rendering index Ra is improved and the light-emitting efficiency is improved by mounting the red semiconductor chip on the light-emitting module mixedly with another color semiconductor chip.

However, if a blue semiconductor chip and the red semiconductor chip are mixedly mounted, the area of the light-emitting module increases. The red semiconductor chip has a light decrease ratio to temperature larger than a light decrease ratio of the blue semiconductor chip. Therefore, if an actual working temperature is taken into account, a large number of red semiconductor chips are necessary. Therefore, the area of the light-emitting module further increases and luminous excitance is deteriorated. Further, it is difficult to mix lights excited by the red semiconductor chip and the blue semiconductor chip. This causes color unevenness on an irradiation surface.

As a method of solving these problems, it is conceivable to use a line red phosphor having a specific light emission peak without using the red semiconductor chip. However, the line red phosphor includes fluorine. Therefore, it is likely that hydrofluoric acid is generated because of affinity of the fluorine and the water in the atmosphere and deterioration (e.g., a color shift) of the line red phosphor occurs.

### BRIEF DESCRIPTION OF THE DRAWINGS

FIG. 1A is a schematic sectional view of a light-emitting module according to a first embodiment,

FIG. 1B is an enlarged schematic sectional view of a phosphor provided in the light-emitting module;

FIG. 2A is a diagram showing a light emission spectrum of a red phosphor according to the first embodiment,

FIG. 2B is a schematic sectional view showing a process of formation of a protection film on the surface of the red phosphor;

FIG. 3A is a schematic sectional view of a light-emitting module according to a first variation of the first embodiment,

FIG. 3B is a schematic sectional view of a light-emitting module according to a second variation of the first embodiment; and

FIG. 4 is a schematic sectional view of a luminaire according to a second embodiment.

### DETAILED DESCRIPTION

In general, according to one embodiment, there is provided a light-emitting module including: a substrate; a light-emitting body provided on the substrate; and a phosphor containing layer provided on the substrate and the light-emitting body, the phosphor containing layer including a first phosphor excited by emitted light of the light-emitting body, having a light emission peak in a wavelength range equal to or greater than 610 nm and less than 655 nm, and having a surface covered with a protection film.

Various embodiments will be described hereinafter with reference to the accompanying drawings. In the following explanation, the same members are denoted by the same reference numerals and signs. Explanation of members once explained is omitted as appropriate.

### First Embodiment

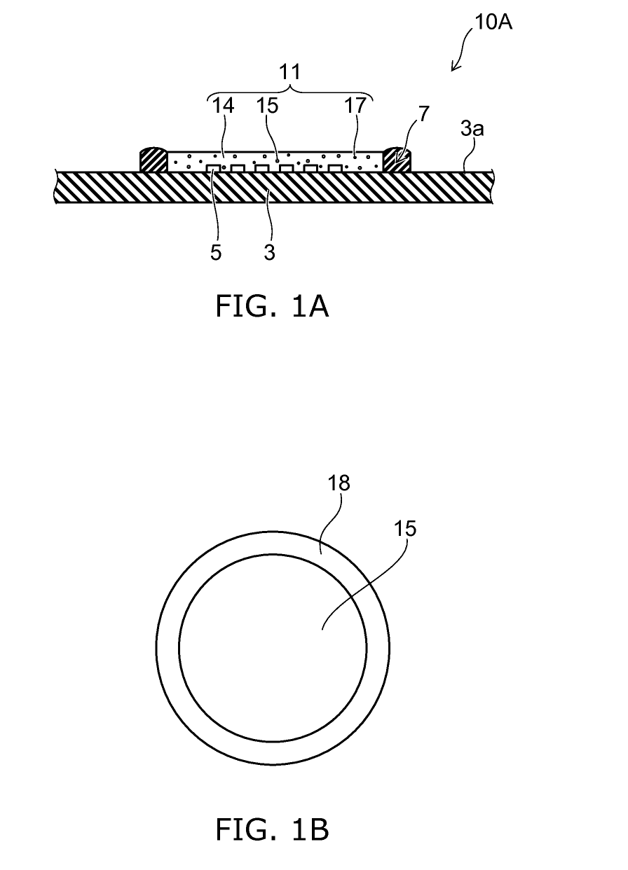

FIG. 1A is a schematic sectional view of a light-emitting module according to a first embodiment. FIG. 1B is an enlarged schematic sectional view of a phosphor provided in the light-emitting module according to the first embodiment.

As shown in FIG. 1A, a light-emitting module 10A includes a substrate 3, a plurality of light-emitting bodies 5, a phosphor containing layer 11, and a bank 7. The light-emitting module 10A is a light-emitting module of a so-called COB (Chip On Board) type.

The plurality of light-emitting bodies 5 are provided on the substrate 3. The substrate 3 is, for example, a ceramic substrate. The light-emitting body 5 emits light having a wavelength of 400 to 480 (nm) and excites a red phosphor 15 and a yellow phosphor 17. The light-emitting body 5 is a light-emitting diode (LED) and emits, for example, blue light having a dominant wavelength of 440 to 465 nm.

The light-emitting body 5 is mounted on, for example, an upper surface 3a of the substrate 3 via an adhesive. The plurality of light-emitting bodies 5 are mounted on the substrate 3 and connected in series or in parallel using a metal wire. The bank 7 is provided to surround a region where the plurality of light-emitting bodies 5 are mounted. The bank 7 includes, for example, a white resin.

The phosphor containing layer 11 is provided on the substrate 3 and on the light-emitting bodies 5. The phosphor containing layer 11 includes a translucent resin 14 such as silicone, the red phosphor 15 (a first phosphor), and the yellow phosphor 17 (a second phosphor). For example, the red phosphor 15 and the yellow phosphor 17 are dispersed in the translucent resin 14 in the phosphor containing layer 11.

The red phosphor 15 is excited by emitted light of the light-emitting body 5 and has a light emission peak in a wavelength range equal to or greater than 610 nm and less than 655 nm. The red phosphor 15 includes, for example, a phosphor represented by a chemical formula K₂SiF₆:Mn. The surface of the red phosphor 15 is covered with a protection film 18 (FIG. 1B). The protection film 18 includes, for example, an oxide.

The yellow phosphor 17 is excited by emitted light of the light-emitting body 5 and has a light emission peak in a wavelength range between a peak wavelength of a light emission spectrum of the light-emitting body 5 and a peak wavelength of a light emission spectrum of the red phosphor 15. The yellow phosphor 17 is, for example, a YAG phosphor.

In the phosphor containing layer 11, a green phosphor may be used instead of the yellow phosphor 17 or the green phosphor may be dispersed besides the red phosphor 15 and the yellow phosphor 17.

In the light-emitting module 10A, for example, the translucent resin 14, in which the red phosphor 15 and the yellow phosphor 17 are dispersed, is poured into the inner side of the bank 7 and hardened. Consequently, the phosphor containing layer 11 configured to cover the light-emitting bodies 5 is provided. The correlated color temperature of the light-emitting module 10A is, for example, 2700 to 5500 K. An average color rendering index of the light-emitting module 10A is, for example, equal to or higher than 85.

The red phosphor 15 according to the first embodiment is described more in detail.

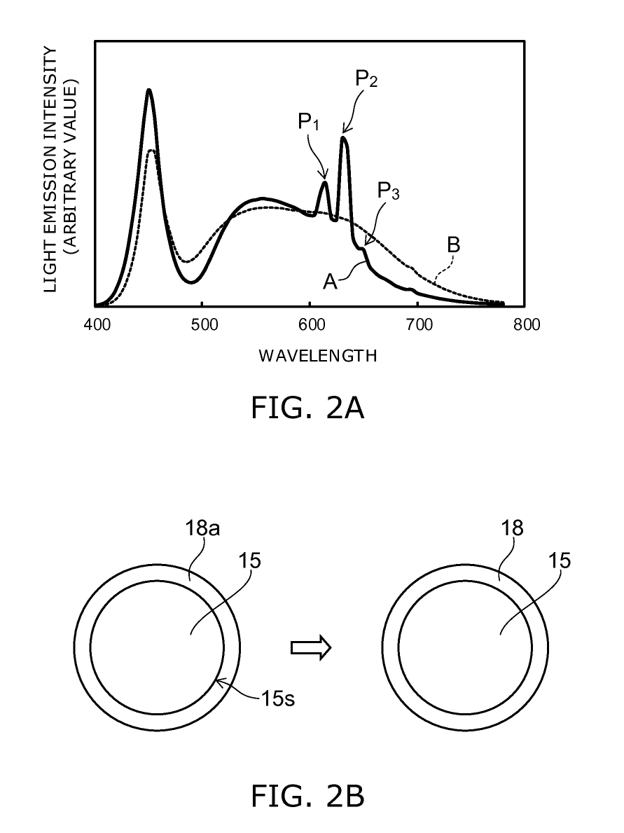

FIG. 2A is a diagram showing a light emission spectrum of the red phosphor according to the first embodiment. FIG. 2B is a schematic sectional view showing a process of formation of the protection film on the surface of the red phosphor according to the first embodiment.

The abscissa of FIG. 2A indicates a light emission wavelength λ and the ordinate of FIG. 2A indicates light emission intensity I_{L} (an arbitrary value). A line A in the figure represents a light emission spectrum of the K₂SiF₆:Mn phosphor included in the red phosphor 15. A line B in the figure represents a light emission spectrum of a CASN phosphor according to a comparative example.

As represented by the line A, the K₂SiF₆:Mn phosphor has light mission peaks P₁ (λ: near 610 nm), P₂ (λ: near 630), and P₃ (λ: near 650) having half width equal to or smaller than 20 nm in a wavelength region equal to or greater than 610 nm and less than 655 nm. The light emission intensity I_{L} in a wavelength region equal to or greater than 655 nm is equal to or smaller than a half of the light emission peaks P₁ and P₂.

On the other hand, as represented by the line B, the CASN phosphor has a broad light emission peak in a wavelength range of 500 to 700 nm. Half width of the light emission peak reaches about 170 nm. Light emission intensity at a wavelength of 650 nm is about 80% of light emission intensity at the peak wavelength.

In the K₂SiF₆:Mn phosphor, the intensity of a light emission spectrum in a wavelength band equal to or greater than 650 nm, where relative visibility falls, is lower than the intensity of the CASN phosphor. Therefore, if a correlated color temperature and an average color rendering index are the same, a luminous flux is larger in the light-emitting module in which the K₂SiF₆:Mn phosphor is used than in the CASN phosphor. That is, the light-emitting module having higher light-emitting efficiency is obtained.

The red phosphor 15, the surface of which is covered with the protection film 18, is formed by, for example, a method shown in FIG. 2B. First, as shown in the left diagram of FIG. 2B, after the red phosphor 15 including K₂SiF₆:Mn is prepared, a K₂SiF₆ layer 18a, in which Mn (manganese) is not substituted, is formed on a surface 15s of the red phosphor 15. Subsequently, the K₂SiF₆ layer 18a is oxidized, whereby, as shown in the right drawing of FIG. 2B, the K₂SiF₆ layer 18a is changed to an oxide (e.g., SiO₂) of silicon (Si) included in the K₂SiF₆ layer 18a. In a process in which the silicon oxide is preferentially formed, K (potassium) and F (fluorine) are removed.

A component of the protection film 18 is not limited to the silicon oxide and only has to be a material having a refractive index equal to or higher than the refractive index of a silicone resin and having light transmittance at a wavelength equal to or greater than 400 nm. For example, the component of the protection film 18 may be aluminum oxide (Al₂O₃), titanium oxide (TiO₂), or the like. As a method of forming the protection film 18 on the surface of the red phosphor 15, a complex method, a sol-gel method, or the like is adopted.

An effect of the light-emitting module 10A according to the first embodiment is described below.

For example, as light-emitting modules of a COB type, a first light-emitting module for comparison A, a second light-emitting module for comparison B, and the light-emitting module 10A according to the first embodiment were prepared. In the light-emitting modules, on the substrate 3, seven light-emitting bodies 5 are mounted in series and twenty-four rows of the seven light-emitting bodies 5 are mounted in parallel. A dimension of a light-emitting section of each of the light-emitting modules is 13 mm×17 mm.

On the inner side of the bank 7 of the light-emitting module A, the translucent resin 14 in which a yellow phosphor (YAG), a green phosphor (G-YAG), and a red phosphor (CASN) are dispersed is arranged as a phosphor containing layer. The translucent resin 14 is, for example, a methyl silicone resin. The average color rendering index Ra of the light-emitting module A is 89 and the correlated color temperature of the light-emitting module A is 2900 K.

In the light-emitting module B, the red phosphor 15 (K₂SiF₆:Mn) not provided with the protection film 18 is used instead of the red phosphor (CASN) of the light-emitting module A. Components other than the red phosphor 15 are the same as the components of the light-emitting module A.

In the light-emitting module 10A, the red phosphor 15 (K₂SiF₆:Mn) provided with the protection film 18 is used instead of the red phosphor (CASN) of the light-emitting module A. Components other than the red phosphor 15 are the same as the components of the light-emitting module A.

Among the light-emitting modules, the light-emitting efficiency of the light-emitting module B and the light-emitting module 10A rose to “115” compared with the light-emitting efficiency of the light-emitting module A assumed to be “100”. In the light-emitting module B and the light-emitting module 10A, K₂SiF₆:Mn is used as the red phosphor. Therefore, the light-emitting efficiency of the light-emitting module B and the light-emitting module 10A rises more than the light-emitting efficiency of the light-emitting module A.

In the light-emitting module B, compared with a correlated color temperature after 100 hours elapsed from the start of lighting, a correlated color temperature after 1000 hours elapsed from the start of lighting rose Δ110 K. However, in the light-emitting module 10A, compared with the correlated color temperature after 100 hours elapsed from the start of lighting, the correlated color temperature after 1000 hours elapsed from the start of lighting only rose Δ30 K.

In the light-emitting module B, the surface of the red phosphor 15 is not covered with the protection film 18. The red phosphor 15 includes fluorine having affinity with water. Therefore, the water in the atmosphere diffuses in the translucent resin 14 and directly comes into contact with the red phosphor 15. As a result, if the light-emitting module B is continuously used for a long time, deterioration of the red phosphor 15 sometimes occurs in the light-emitting module B.

On the other hand, in the light-emitting module 10A, the surface of the red phosphor 15 is covered with the protection film 18. Therefore, even if the light-emitting module 10A is continuously used for a long time, in the light-emitting module 10A, the red phosphor 15 is protected by the protection film 18. Deterioration of the red phosphor 15 is suppressed compared with the light-emitting module B.

As explained above, the light-emitting module 10A has the high color rendering index and the high light-emitting efficiency. Deterioration of the red phosphor 15 is suppressed. That is, in the first embodiment, the light-emitting module 10A is realized that has the high color rendering index and the high light-emitting efficiency and in which a color shift less easily occurs.

### Variation of the First Embodiment

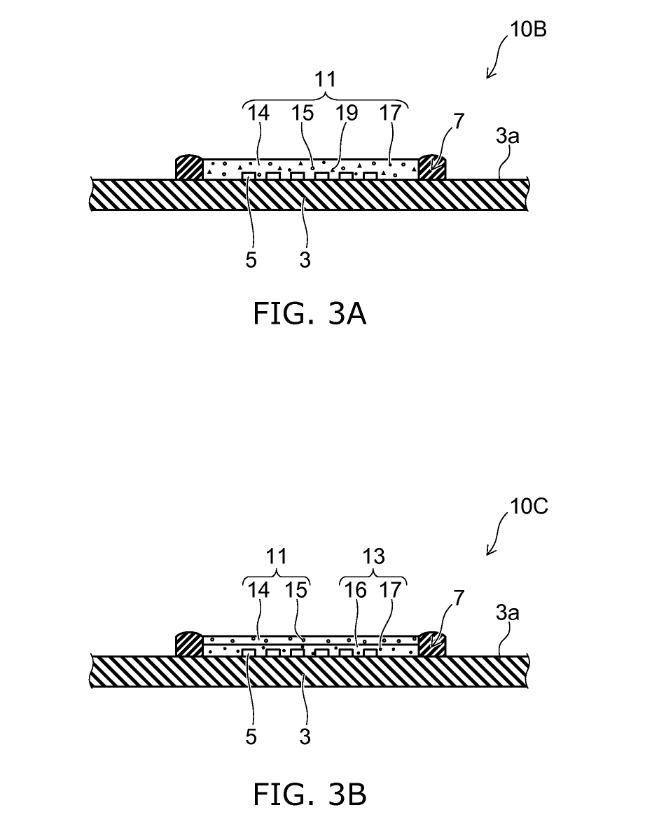

FIG. 3A is a schematic sectional view of a light-emitting module according to a first variation of the first embodiment. FIG. 3B is a schematic sectional view of a light-emitting module according to a second variation of the first embodiment.

In a light-emitting module 10B shown in FIG. 3A, in addition to the components of the light-emitting module 10A, the phosphor containing layer 11 further includes oxide particles 19. The oxide particles 19 are, for example, oxide particles having a refractive index higher than the refractive index of the translucent resin 14. The oxide is, for example, a titanium oxide (TiO₂). In the light-emitting module 10B, as in the light-emitting module 10A, the surface of the red phosphor 15 is covered with the protection film 18.

It is known that, among red phosphors, K₂SiF₆:Mn has a low refractive index compared with the other red phosphors. Therefore, if the light-emitting body 5 is covered with the phosphor containing layer 11 including the red phosphor 15, it is likely that efficiency of extracting light from the light-emitting body 5 is deteriorated in a light-emitting module.

On the other hand, in the light-emitting module 10B, the decrease in the refractive index of the phosphor containing layer 11 due to the mixing of the red phosphor 15 is suppressed by mixing the oxide particles 19 having the high refractive index in the phosphor containing layer 11. Consequently, in the light-emitting module 10B, the deterioration in the light-emitting efficiency is suppressed. For example, it is known that, if the light-emitting efficiency of the light-emitting module 10A is assumed to “100”, the light-emitting efficiency of the light-emitting module 10B, in which the titanium oxide particles are dispersed in the phosphor containing layer 11, rises to “107”.

The phosphor containing layer does not need to be a single layer and may be formed by, for example, a plurality of layers.

For example, as shown in FIG. 3B, a light-emitting module 10C includes the phosphor containing layer 11 and a phosphor containing layer 13. The phosphor containing layer 11 includes the red phosphor 15 and the translucent resin 14. The phosphor containing layer 13 includes the yellow phosphor 17 and a translucent resin 16. The phosphor containing layer 13 is provided between the light-emitting bodies 5 and the phosphor containing layer 11. That is, on the substrate 3, the yellow phosphor 17 is arranged between the red phosphor 15 and the light-emitting bodies 5. As the phosphor 17, a green phosphor may be used or a phosphor obtained by mixing a yellow phosphor and a green phosphor may be used. The oxide particles 19 may be mixed in the phosphor containing layer 11.

### Second Embodiment

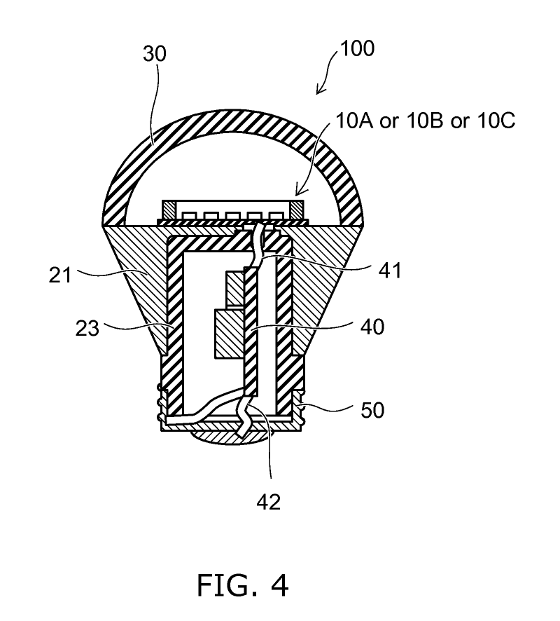

FIG. 4 is a schematic sectional view of a luminaire according to a second embodiment.

Any one of the light-emitting modules 10A to 10C is incorporated in a luminaire 100 as a light source. The luminaire 100 is, for example, a bulb-type lamp. The luminaire 100 includes any one of the light-emitting modules 10A to 10C, a housing 21 mounted with any one of the light-emitting modules 10A to 10C, and a cover 30 configured to cover any one of the light-emitting modules 10A to 10C. The luminaire 100 is one example. The embodiments are not limited to the luminaire 100.

On the inside of the housing 21, a power converting section 40 configured to supply electric power to any one of the light-emitting modules 10A to 10C is provided. The power converting section 40 is electrically connected to any one of the light-emitting modules 10A to 10C and a cap 50 via lead wires 41 and 42. The power converting section 40 is housed in an insulating case 23 provided on the inside of the housing 21. The power converting section 40 receives the supply of alternating-current power from a not-shown commercial power supply via the cap 50, converts the alternating-current power into, for example, direct-current power, and supplies the direct-current power to any one of the light-emitting modules 10A to 10C.

Any one of the light-emitting modules 10A to 10C receives the supply of electric power from the power converting section 40 and emits white light. That is, the light-emitting module emits white light obtained by mixing blue light emitted from the light-emitting body 5, red light emitted from the red phosphor 15, and yellow light emitted from the yellow phosphor 17.

As the light-emitting module, the light-emitting module of the COB type is illustrated. However, a light-emitting module of an SMD (Surface Mount Device) type may be used.

In the embodiments, “a part A is provided on a part B” means that the part A is provided on the part B in contact with the part B and also sometimes means that the part A is provided above the part B not in contact with the part B.

Although the embodiments are described above with reference to the specific examples, the embodiments are not limited to these specific examples. That is, design modification appropriately made by a person skilled in the art in regard to the embodiments is within the scope of the embodiments to the extent that the features of the embodiments are included. Components and the disposition, the material, the condition, the shape, and the size or the like included in the specific examples are not limited to illustrations and can be changed appropriately.

The components included in the embodiments described above can be combined to the extent of technical feasibility and the combinations are included in the scope of the embodiments to the extent that the feature of the embodiments is included. Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A light-emitting module comprising:
a substrate;
a light-emitting body provided on the substrate; and
a phosphor containing layer provided on the substrate and the light-emitting body, the phosphor containing layer including a first phosphor excitable by emitted light of the light-emitting body, having a light emission peak in a wavelength range equal to or greater than 610 nm and less than 655 nm, and a surface of the first phosphor being covered with a protection film, the first phosphor including K₂SiF₆:Mn.

2. The module according to claim 1, wherein the phosphor containing layer further includes oxide particles.

3. The module according to claim 1, wherein:
the phosphor containing layer further includes a second phosphor, and
the second phosphor is excitable by the emitted light of the light-emitting body and has a light emission peak in a wavelength range between a peak wavelength of a light emission spectrum of the light-emitting body and a peak wavelength of a light emission spectrum of the first phosphor.

4. The module according to claim 2, wherein:
the phosphor containing layer further includes a second phosphor, and
the second phosphor is excited excitable by the emitted light of the light-emitting body and has a light emission peak in a wavelength range between a peak wavelength of a light emission spectrum of the light-emitting body and a peak wavelength of a light emission spectrum of the first phosphor.

5. The module according to claim 3, wherein
the phosphor containing layer includes a two-layer structure of a layer including the first phosphor and a layer including the second phosphor.

6. The module according to claim 5, wherein the layer including the first phosphor is provided on the layer including the second phosphor.

7. The module according to claim 1, wherein a wavelength of light emitted from the light-emitting body is 400 nm to 480 nm.

8. (canceled)

9. The module according to claim 1, wherein the phosphor containing layer includes a translucent resin in which the first phosphor is dispersed.

10. The module according to claim 9, wherein:
the translucent resin includes a silicone resin, and
a refractive index of the protection film is equal to or higher than a refractive index of the silicone resin.

11. The module according to claim 1, wherein the protection film includes an oxide.

12. The module according to claim 11, wherein the oxide includes one of a silicon oxide, an aluminum oxide, and a titanium oxide.

13. The module according to claim 2, wherein:
the phosphor containing layer includes a translucent resin, and
the oxide particles have a refractive index higher than a refractive index of the translucent resin.

14. The module according to claim 13, wherein the oxide particles include a titanium oxide.

15. A luminaire comprising:
a housing; and
a light-emitting module mounted on the housing, the light-emitting module including:
a substrate;
a light-emitting body provided on the substrate; and
a phosphor containing layer provided on the substrate and the light-emitting body, the phosphor containing layer including a first phosphor excited by emitted light of the light-emitting body, having a light emission peak in a wavelength range equal to or greater than 610 nm and less than 655 nm, and a surface of the first phosphor being covered with a protection film, the first phosphor including K₂SiF₆:Mn.

16. The module according to claim 1, wherein the protection film is configured to protect the surface of the first phosphor from water.
